(19) United States
(12) Patent Application Publication
(10) Pub. No.: US 2016/0351607 A1
(43) Pub. Date: Dec. 1, 2016

(54) IMAGE SENSING DEVICE

(71) Applicant: XINTEC INC., Taoyuan City (TW)

(72) Inventors: Tsang-Yu LIU, Zhubei City (TW); Chi-Chang LIAO, Zhubei City (TW)

(21) Appl. No.: 15/166,261

(22) Filed: May 27, 2016

Related U.S. Application Data
(60) Provisional application No. 62/167,539, filed on May 28, 2015.

(51) Int. Cl. H01L 27/146

(52) U.S. Cl. CPC H01L 27/14618; H01L 27/14632; H01L 27/14687

(57) ABSTRACT

An image sensing device includes a printed circuit board, a chip package, and an adhesive layer. The printed circuit board has a concave portion. The chip package has a sensing surface and a bonding surface that is opposite to the sensing surface. The adhesive layer is disposed between the bonding surface of the chip package and the concave portion of the printed circuit board. The adhesive layer has an aggregation force. The chip package is bent through a surface of the concave portion and the aggregation force, such that the sensing surface of the chip package is an arc surface.

### RELATED APPLICATIONS

This application claims priority to U.S. provisional Application Ser. No. 62/167,539, filed May 28, 2015, which is herein incorporated by reference.

### BACKGROUND

### Field of Invention

The present invention relates to an image sensing device.

### Description of Related Art

In manufacturing an image sensing device, a chip package may be disposed on a printed circuit board though a soldering technology or a surface mount technology (SMT), such that solder balls on a back surface of the chip package can be electrically connected to contacts of the printed circuit board.

Because the sizes of the solder balls are substantially the same and the configuration of the chip package is not designed specifically, the conventional chip package is parallel to the printed circuit board, such that the front surface of the chip package (i.e., an image sensing surface) is a horizontal surface. As a result, when the image sensing surface of the chip package detects an image, light is apt to be scattered, thus causing image distortion.

In addition, when the miniaturization of the image sensing device is required, the chip package formed by utilizing the solder balls to bond to the printed circuit board may cause the total thickness of the chip package to be difficultly reduced.

### SUMMARY

An aspect of the present invention is to provide an image sensing device.

According to an embodiment of the present invention, an image sensing device includes a printed circuit board, a chip package, and an adhesive layer. The printed circuit board has a concave portion. The chip package has a sensing surface and a bonding surface that is opposite to the sensing surface. The adhesive layer is disposed between the bonding surface of the chip package and the concave portion of the printed circuit board. The adhesive layer has an aggregation force. The chip package is bent through a surface of the concave portion and the aggregation force, such that the sensing surface of the chip package is an arc surface.

In the aforementioned embodiment of the present invention, since the adhesive layer is disposed between the bonding surface of the chip package and the concave portion of the printed circuit board, the chip package may be bent through the surface of the concave portion and the aggregation force of the adhesive layer. As a result, the sensing surface of the chip package is an arc surface that may be simulated as the shape of a retina. When the sensing surface of the chip package detects an image, light is easily focused, thereby reducing the probability of image distortion. In addition, in the image sensing device, the adhesive layer is utilized to adhere the chip package to the concave portion of the printed circuit board without needing to use solder balls of a conventional ball grid array to bond the chip package to the printed circuit board, thereby reducing the total thickness of the image sensing device. Such a design is helpful to the miniaturization of the image sensing device.

Another aspect of the present invention is to provide an image sensing device.

According to an embodiment of the present invention, an image sensing device includes a printed circuit board, a chip package, a plurality of conductive structures, and an adhesive layer. The chip package has a central region, an edge region that surrounds the central region, a sensing surface, and a bonding surface that is opposite to the sensing surface. The conductive structures are disposed between the printed circuit board and the edge region of the chip package. The adhesive layer is disposed between the bonding surface of the chip package and the printed circuit board. The adhesive layer has an aggregation force. The chip package is bent through the aggregation force and the conductive structures, such that the sensing surface of the chip package is an arc surface.

In the aforementioned embodiment of the present invention, since the adhesive layer is disposed between the bonding surface of the chip package and the printed circuit board, and the conductive structures are disposed between the printed circuit board and the edge region of the chip package, the chip package may be bent through the aggregation force and the conductive structures. As a result, the sensing surface of the chip package is an arc surface that may be simulated as the shape of a retina. When the sensing surface of the chip package detects an image, light is easily focused, thereby reducing the probability of image distortion.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a cross-sectional view of an image sensing device according to one embodiment of the present invention;

FIG. 2 is a partially enlarged view of a chip package shown in FIG. 1;

FIG. 3 is a cross-sectional view of an image sensing device according to one embodiment of the present invention;

FIG. 4 is a cross-sectional view of an image sensing device according to one embodiment of the present invention;

FIG. 5 is a cross-sectional view of an image sensing device according to one embodiment of the present invention;

FIG. 6 is a cross-sectional view of an image sensing device according to one embodiment of the present invention; and

FIG. 7 is a cross-sectional view of an image sensing device according to one embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

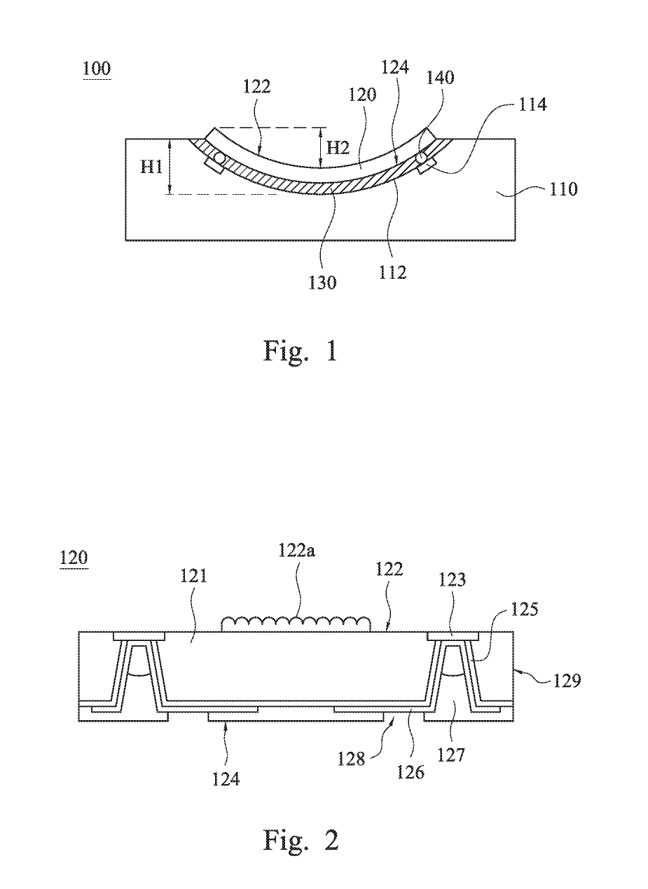

FIG. 1 is a cross-sectional view of an image sensing device 100 according to one embodiment of the present invention. As shown in FIG. 1, the image sensing device 100 includes a printed circuit board 110, a chip package 120, and an adhesive layer 130. The printed circuit board 110 has a concave portion 112. The chip package 120 has a sensing surface 122 and a bonding surface 124 that is opposite to the sensing surface 122. The adhesive layer 130 is disposed between the bonding surface 124 of the chip package 120 and the concave portion 112 of the printed circuit board 110. The adhesive layer 130 can fix the chip package 120 to the concave portion 112 of the printed circuit board 110. The adhesive layer 130 has an aggregation force. In this embodiment, the chip package 120 is bent through a surface of the concave portion 112 and the aggregation force of the adhesive layer 130, such that the sensing surface 122 of the chip package 120 is an arc surface.

Moreover, an edge of the concave portion 112 of the printed circuit board 110 has an electrical contact 114, and the image sensing device 100 further includes a conductive structure 140. The conductive structure 140 is disposed between the electrical contact 114 and the bonding surface 124 of the chip package 120 to conduct the chip package 120 to the printed circuit board 110. In this embodiment, the conductive structure 140 may be made of a material including gold, such as a gold bump, but the present invention is not limited in this regard.

A perpendicular distance H1 between the edge and the center of the concave portion 112 of the printed circuit board 110 is greater than or equal to 100 μm. Since the bending level of the chip package 120 is similar to that of the surface of the concave portion 112, a perpendicular distance H2 between the edge and the center of the chip package 120 is also greater than or equal to 100 μm to ensure that the sensing surface 122 has sufficient curvature to receive an external image.

Since the sensing surface 122 of the chip package 120 is an arc surface, the arc surface of the chip package 120 may be simulated as the shape of a retina. When the sensing surface 122 of the chip package 120 detects an image, light is easily focused, thereby reducing the probability of image distortion. In addition, in the image sensing device 120, the adhesive layer 130 is utilized to adhere the chip package 120 to the concave portion 112 of the printed circuit board 110 without needing to use solder balls of a conventional ball grid array to bond the chip package 120 to the printed circuit board 110, thereby reducing the total thickness of the image sensing device 100. Such a design is helpful to the miniaturization of the image sensing device 100.

In this embodiment, the coefficient of thermal expansion of the adhesive layer 130 may be greater than that of the chip package 120. In manufacturing the image sensing device 100, a high temperature environment may cause the expansion level of the adhesive layer 130 to be greater than that of the chip package 120, such that the adhesive layer 130 forms an aggregation force to bend the chip package 120 for ensuring the sensing surface 122 having sufficient curvature. In the following description, the structure of the chip package 120 will be described.

FIG. 2 is a partially enlarged view of the chip package 120 shown in FIG. 1. As shown in FIG. 1 and FIG. 2, the chip package 120 includes a substrate 121, a sensing element 122a, a conductive pad 123, an isolation layer 125, a redistribution layer 126 (RDL), and a passivation layer 127. The substrate 121 is made of a material including silicon, which may be an image sensing chip. The redistribution layer 126 is electrically connected to the conductive pad 123, and at least one portion of the redistribution layer 126 is exposed through the opening 128 of the passivation layer 127. The conductive structure 140 of FIG. 1 is in contact with the redistribution layer 126 that is in the opening 128, such that the conductive pad 123 is electrically connected to the electrical contact 114 of the printed circuit board 110. It is noted that the structure of the chip package 120 shown in FIG. 2 is merely an example. The present invention is not limited to the number of the conductive pad 123 and the number of the redistribution layer 126, and the positions of the redistribution layer 126 for being exposed may be determined as deemed necessary by designers.

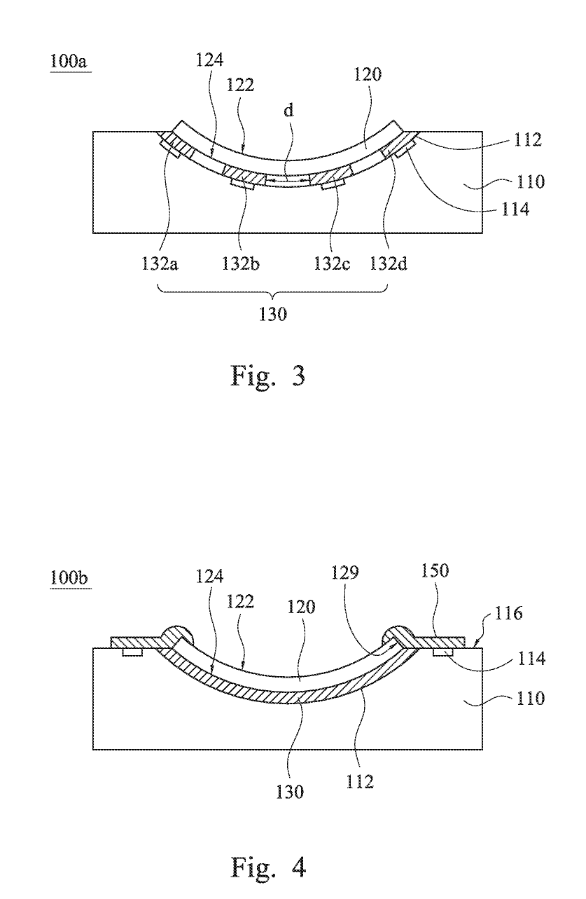

FIG. 3 is a cross-sectional view of an image sensing device 100a according to one embodiment of the present invention. The image sensing device 100a includes the printed circuit board 110, the chip package 120, and the adhesive layer 130. The difference between this embodiment and the embodiment shown in FIG. 1 is that the surface of the concave portion 112 of the printed circuit board 110 has electrical contacts 114, and the adhesive layer 130 includes conductive adhesives 132a, 132b, 132c, 132d. A gap d is formed between two adjacent conductive adhesives (e.g., the conductive adhesives 132b, 132c), and each of the conductive adhesives 132a, 132b, 132c, 132d is disposed between one of the electrical contacts 114 and the bonding surface 124 of the chip package 120. Each of the conductive adhesives 132a, 132b, 132c, 132d may be a double-sided adhesive, but the present invention is not limited in this regard.

In this embodiment, the adhesive layer 130 may be used to electrically connect the chip package 120 to the printed circuit board 110, and the image sensing device 100a does not need to have the conductive structure 140 of FIG. 1. The conductive adhesives 132a, 132b, 132c, 132d are substantially aligned with the electrical contacts 114 and the exposed positions of the redistribution layer 126 (see FIG. 2), such that the chip package 120 may be electrically connected to the printed circuit board 110 through the conductive adhesives 132a, 132b, 132c, 132d.

FIG. 4 is a cross-sectional view of an image sensing device 100b according to one embodiment of the present invention. The image sensing device 100b includes the printed circuit board 110, the chip package 120, and the adhesive layer 130. The chip package 120 has a side surface 129 that is adjacent to the sensing surface 122 and the bonding surface 124. The difference between this embodiment and the embodiment shown in FIG. 1 is that the chip package 120 of the image sensing device 100b has no redistribution layer 126 of FIG. 2. Moreover, the surface 116 of the printed circuit board 110 adjacent to the concave portion 112 has the electrical contact 114, and the image sensing device 100b further includes a conductive adhesive 150. The conductive adhesive 150 is located on the electrical contact 114 and the side surface 129 of the chip package 120, such that the chip package 120 is electrically connected to the printed circuit board 110 through the conductive adhesive 150. For example, the side surface 129 of the chip package 120 of the image sensing device 100b may have an electrical pad or a redistribution layer to electrically connect to the conductive adhesive 150, but there is no redistribution layer on the bottom of the chip package 120 adjacent to the adhesive layer 130.

In this embodiment, the conductive adhesive 150 may be made of a material including silver, such as silver paste, but the present invention is not limited in this regard.

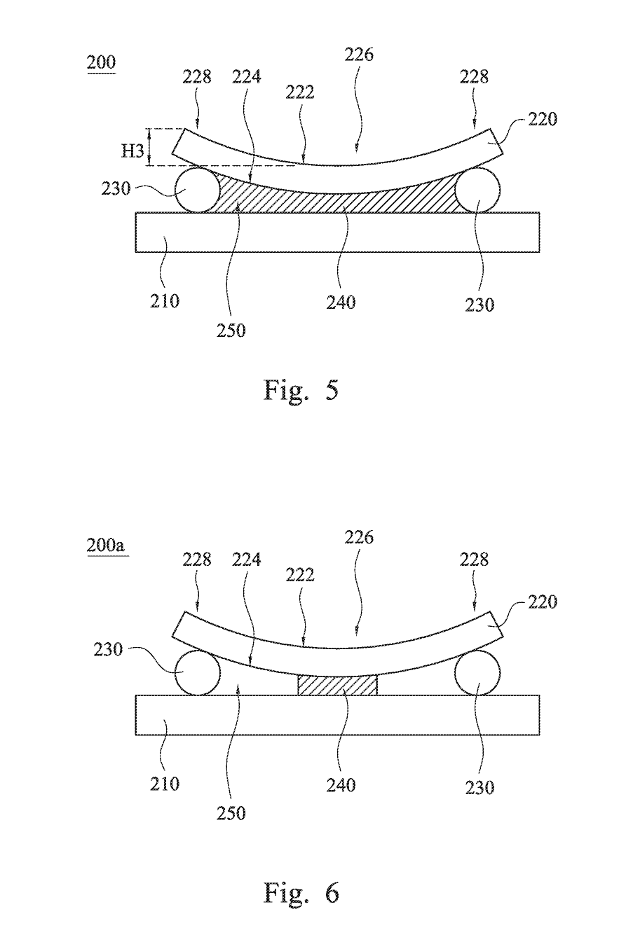

FIG. 5 is a cross-sectional view of an image sensing device 200 according to one embodiment of the present invention. As shown in FIG. 5, the image sensing device 200 includes a printed circuit board 210, a chip package 220, conductive structures 230, and an adhesive layer 240. The chip package 220 has a central region 226, an edge region 228 that surrounds the central region 226, a sensing surface 222, and a bonding surface 228 that is opposite to the sensing surface 222. For example, the structure of the chip package 220 may be the same as the structure shown in FIG. 2. The conductive structures 230 are disposed between the printed circuit board 210 and the edge region 228 of the chip package 220. The conductive structures 230 may be electrically connected to the redistribution layer of the chip package 220, such as the redistribution layer 126 in the opening 128 of the passivation layer 127 shown in FIG. 2. The adhesive layer 240 is disposed between the bonding surface 224 of the chip package 220 and the printed circuit board 210. The adhesive layer 240 has an aggregation force. The chip package 220 is bent through the aggregation force and the conductive structures 230, such that the sensing surface 222 of the chip package 220 is an arc surface.

In this embodiment, a space 250 is formed among the conductive structures 230, the printed circuit board 210, and the chip package 220, and the space 250 is filled with the adhesive layer 240. The conductive structures 230 may be made of a material including tin, such as solder balls of a ball grid array, but the present invention is not limited in this regard. In addition, the conductive structures 230 support the bonding surface 228 of the chip package 220, and the adhesive layer 240 can be used at the same time, such that a perpendicular distance H3 between the edge region 228 and the central region 226 of the chip package 220 may be controlled to be greater than or equal to 100 μm. Such a design may ensure that the sensing surface 222 has sufficient curvature to receive an external image.

When the image sensing device 200 is in use, since the sensing surface 222 of the chip package 220 is an arc surface, the arc surface of the chip package 220 may be simulated as the shape of a retina. When the sensing surface 222 of the chip package 220 detects an image, light is easily focused, thereby reducing the probability of image distortion.

FIG. 6 is a cross-sectional view of an image sensing device 200a according to one embodiment of the present invention. The image sensing device 200a includes the printed circuit board 210, the chip package 220, the conductive structures 230, and the adhesive layer 240. The difference between this embodiment and the embodiment shown in FIG. 5 is that the adhesive layer 240 is disposed only between the central region 226 of the chip package 220 and the printed circuit board 210. As a result of such a design, the chip package 220 may be bent through the aggregation force of the adhesive layer 240 and the supporting forces of the conductive structures, such that the sensing surface 222 of the chip package 220 is an arc surface. Compared with the device shown in FIG. 5, the usage amount of the adhesive layer 240 of the image sensing device 200a is less than that of the image sensing device 200, thereby reducing the cost of the adhesive layer 240.

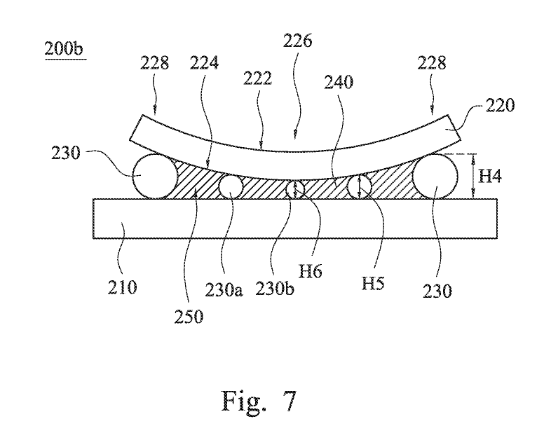

FIG. 7 is a cross-sectional view of an image sensing device 200b according to one embodiment of the present invention. The image sensing device 200b includes the printed circuit board 210, the chip package 220, the conductive structures 230, and the adhesive layer 240. The difference between this embodiment and the embodiment shown in FIG. 5 is that the image sensing device 200b further includes a plurality of sub-conductive structures 230a, 230b. The sub-conductive structures 230a, 230b are disposed between the printed circuit board 210 and the chip package 220 and in the space 250. The height of each of the sub-conductive structures 230a, 230b is smaller than the height H4 of each of the conductive structures 230.

In this embodiment, the height H4 of the conductive structure 230 is greater than the height H5 of the sub-conductive structure 230a, and the height H5 of the sub-conductive structure 230a is greater than the height H6 of the sub-conductive structure 230b. In other words, the sub-conductive structures 230a, 230b have different heights, and the heights of the sub-conductive structures 230a, 230b are gradually increased from the central region 226 of the chip package 220 to the edge region 228 of the chip package 220.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims.

What is claimed is:

1. An image sensing device, comprising:
a printed circuit board having a concave portion;
a chip package having a sensing surface and a bonding surface that is opposite to the sensing surface; and
an adhesive layer disposed between the bonding surface of the chip package and the concave portion of the printed circuit board, wherein the adhesive layer has an aggregation force; and the chip package is bent through a surface of the concave portion and the aggregation force, such that the sensing surface of the chip package is an arc surface.

2. The image sensing device of claim 1, wherein an edge of the concave portion of the printed circuit board has an electrical contact, and the image sensing device further comprises:
a conductive structure disposed between the electrical contact and the bonding surface of the chip package.

3. The image sensing device of claim 2, wherein the conductive structure is made of a material comprising gold.

4. The image sensing device of claim 1, wherein the surface of the concave portion of the printed circuit board has a plurality of electrical contacts, and the adhesive layer comprises a plurality of conductive adhesives, and a gap is formed between two adjacent conductive adhesives, and each of the conductive adhesives is disposed between one of the electrical contacts and the bonding surface of the chip package.

5. The image sensing device of claim 1, wherein a surface of the printed circuit board adjacent to the concave portion has an electrical contact, and the chip package has a side surface that is adjacent to the sensing surface and the bonding surface, and the image sensing device further comprises:
a conductive adhesive located on the electrical contact and the side surface of the chip package.

6. The image sensing device of claim 5, wherein the conductive adhesive is made of a material comprising silver.

7. The image sensing device of claim 1, wherein a perpendicular distance between an edge and a center of the concave portion of the printed circuit board is greater than or equal to 100 μm.

8. The image sensing device of claim 1, wherein a perpendicular distance between an edge and a center of the chip package is greater than or equal to 100 μm.

9. The image sensing device of claim 1, wherein a coefficient of thermal expansion of the adhesive layer is greater than a coefficient of thermal expansion of the chip package.

10. The image sensing device of claim 1, wherein there is no redistribution layer on a bottom of the chip package adjacent to the adhesive layer.

11. An image sensing device, comprising:
a printed circuit board;
a chip package having a central region, an edge region that surrounds the central region, a sensing surface, and a bonding surface that is opposite to the sensing surface;
a plurality of conductive structures disposed between the printed circuit board and the edge region of the chip package; and
an adhesive layer disposed between the bonding surface of the chip package and the printed circuit board, wherein the adhesive layer has an aggregation force; and the chip package is bent through the aggregation force and the conductive structures, such that the sensing surface of the chip package is an arc surface.

12. The image sensing device of claim 11, wherein the adhesive layer is disposed between the central region of the chip package and the printed circuit board.

13. The image sensing device of claim 11, wherein a space is formed among the conductive structures, the printed circuit board, and the chip package, and the space is filled with the adhesive layer.

14. The image sensing device of claim 13, further comprising:
a plurality of sub-conductive structures disposed between the printed circuit board and the chip package and in the space, wherein a height of each of the sub-conductive structures is smaller than a height of each of the conductive structures.

15. The image sensing device of claim 14, wherein the sub-conductive structures have different heights, and the heights of the sub-conductive structures are gradually increased from the central region of the chip package to the edge region of the chip package.

16. The image sensing device of claim 11, wherein the conductive structures are made of a material comprising tin.

17. The image sensing device of claim 11, wherein a perpendicular distance between the edge region and the central region of the chip package is greater than or equal to 100 μm.
